(19) United States
(12) Patent Application Publication
(10) Pub. No.: US 2024/0429001 A1
(43) Pub. Date: Dec. 26, 2024

(54) CMOS RF-MEMS CAPACITIVE SWITCH IMPLEMENTATIONS

(71) Applicant: Nanusens SL, Cerdanyola del Vallès (ES)

(72) Inventors: Josep Montanyà i SILVESTRE, Cerdanyola del Vallès (ES); Marco Antonio LLAMAS MOROTE, Cerdanyola del Vallès (ES)

(21) Appl. No.: 18/745,386

(22) Filed: Jun. 17, 2024

Related U.S. Application Data
(60) Provisional application No. 63/521,898, filed on Jun. 20, 2023.

(51) Int. Cl. H01H 1/00; H01H 11/00

(52) U.S. Cl. CPC H01H 1/0036; H01H 11/00

(57) ABSTRACT

A RF-MEMS capacitive switch including a central apex and a plurality of cells. At least two of the plurality of cells are coupled to opposing sides of the central apex and each of the plurality of cells includes a rotor and a stator. At least one meander spring is coupled to an end of the central apex. The capacitive switch includes a top layer and a bottom layer.

### CROSS-REFERENCE TO RELATED APPLICATIONS

This application claims priority to and the benefit of U.S. Provisional Application No. 63/512,898, filed on Jun. 20, 2023, and entitled “CMOS RF-MEMS CAPACTIVE SWITCH VERSIONS,” the entire contents of which are incorporated herein by reference.

### TECHNICAL FIELD

The present disclosure relates to Microelectromechanical (MEMS) devices and, more particularly, to radio frequency (RF) MEMS switches.

### BACKGROUND

RF MEMS switches are tiny switches made through conventional MEMS fabrication technology. They consume low power and function like a light switch or ohmic switch by opening or closing a contact to transmit a signal across the switch. The mechanical components of the switch are only a few microns in size, and the signal transmitted is in the radio frequency range. An RF Digital Tunable Capacitor (DTC) is typically made with several capacitive switches in parallel.

### SUMMARY

The application, in various implementations, addresses deficiencies associated with existing RF-MEMS capacitive switches. This application describes illustrative devices and fabrication techniques that enable more robust, responsive, and reliable MEMS-based switching using smaller devices at lower cost, while using standard CMOS processing.

Various inventive implementations of RF-MEMS capacitive switches according to the disclosure include, for example: an RF-MEMS capacitive switch with an out of plane or in plane actuation implemented with the BEOL of a standard low resistivity CMOS process (e.g., Version G2v1 or v1a); a second device (i.e., Version G2v1) with a difference to G1v1 in that the line interconnecting stators is routed inside the air cavity box instead to be routed by outside the air cavity box. In this way, electromagnetic (EM) field interaction with the Intermetal dielectric (IMD) is reduced and the Q is improved from 4 to 20; a third device (i.e., Version G2v5) where the M1 layer is not electrically connected to cavity sidewalls and top metal. This Version G2v5 does not have top metal capping (open structure intended for wafer capping packaging). Rotor fingers are attached to a central apex and the apex to M1. Stator fingers are attached to cavity sidewalls. There is no decoupling between RF and DC signals; a fourth version referred to as Version G6v2a based on Version v1a but with DC to RF isolation. Stators interconnecting line is now divided into two parts so DC and RF stator's electrodes can be accessed independently while the rotor is connected to a ground air cavity box); a fifth version referred to as Version G6v6c that includes electrical isolation between RF and DC. A central apex has a capacitive anchorage providing electrical isolation between RF and DC parts. This version also includes pull-on/pull-off DC electrodes that increase the rotor's displacement and ensure there is not self-actuation. To increase capacitive ratio, Cr teeth have been added to the RF rotor finger; a sixth version referred to as Version G7v6c which is the same as Version v6c but with three additional capacitive anchors attached to the M1 layer on the RF unit cell to act as stoppers for the RF rotor. These stoppers are interconnected by a M3 layer line that is suspended inside the air cavity by means of two capacitive anchors and that gets out of the air cavity by means of a double wall feedthrough which is then connected to the RF input line; and a seventh version referred to as G7v6c DTC that includes a first 4 Bit DTC product demonstrator composed of eight G7v6c capacitive switches interconnected to conform each of the four bits. RF input access is a ground-signal-ground (GSG) configuration with a pitch of less than or equal to 500 um. Various implementations described herein include capacitive switches using in plane actuation where movement is parallel to the substrate and/or M1-M6 layers, which may be more suited to CMOS and semiconductor processes that are planar where such MEMS switches are very flat. Regardless, in some implementations, the various capacitive switches described herein may be reconfigured and/or redesigned to support out of plane actuation where movement is perpendicular to the substrate and/or M1-M6 layers.

In one aspect, a RF-MEMS capacitive switch includes a central apex and a plurality of cells where at least two of the plurality of cells are coupled to opposing sides of the central apex. Each of plurality of cells includes a rotor and a stator. At least one meander spring is coupled to an end of the central apex. The RF-MEMS capacitive switch also includes a top layer and a bottom layer.

In some implementations, the RF-MEMS capacitive switch includes two meander springs where each meander spring is coupled to an opposing end of the central apex. The capacitive switch may be actuated in response to an electrostatic force being applied between the stator and the rotor when a voltage difference is applied between them. The rotor and stator may be actuated via an out of plane or in plane actuation.

The capacitive switch may include a plurality of stoppers extending between the top and bottom layers of the capacitive switch to maintain separation between the rotor and stator of each of the plurality of cells. The capacitive switch may include a plurality of capacitive anchors configured to anchor the stator of each cell to the bottom layer. The bottom layer may include an M1 layer and the top layer may include an M6 layer. The rotor of each cell may include a rotor finger that is coupled to the central apex. The central apex may be electrically coupled to the bottom layer.

In some implementations, at least one cavity wall extends at least partially between the bottom and top layers where the at least one cavity wall is coupled to the bottom layer. The capacitive switch may include an air cavity housing arranged adjacent to a portion of the at least one cavity wall. The capacitive switch may include a plurality of cells on each side of the central apex where each of the stators of the cells on a side of the central apex are interconnected via an external line at a layer between the bottom and top layers and along the length of the air cavity housing. The air cavity housing may be defined by an inner wall and an outer wall, where each of the stators are connected to the external line via a feedthrough in the inner and outer walls, to form a first capacitive switch electrode.

In some implementations, the top layer includes a second electrode of the capacitive switch. The capacitive switch may include a plurality of columns between the top layer and bottom layer. The plurality of columns may be distributed along the air cavity housing to prevent the top layer from bending after release. The top layer may include capping and/or a cover over at least one cavity formed by the capacitive switch. The capping may include a plurality of holes to facilitate a release process of the at least one air cavity.

In another aspect, a RF-MEMS capacitive switch includes a central apex and a plurality of cells. At least two of the plurality of cells are coupled to opposing sides of the central apex. Each of plurality of cells includes at least one rotor and at least one DC pull on stator. At least one meander spring is coupled to an end of the central apex. The capacitive switch also includes a top layer and a bottom layer. The at least one rotor may include an RF rotor finger and RF rotor teeth.

In a further aspect, a method for manufacturing a RF-MEMS capacitive switch includes: providing a substrate including semiconductor material; forming a structure of interconnection layers above the substrate including a number of stacked conductive layers and dielectric layers; forming a plurality of cells within the interconnect layers, where each cell has one stator and one rotor; and forming a central apex positioned between at least two of the cells, the central apex being suspended via at least one meander spring positioned on an end of the central apex. In one implementation, the method includes forming two meander springs, where each meander spring being coupled to an opposing end of the central apex.

A reading of the following detailed description and a review of the associated drawings will make apparent the advantages of these and other structures. Both the foregoing general description and the following detailed description serve as an explanation only and do not restrict aspects of the disclosure as claimed.

### BRIEF DESCRIPTION OF THE DRAWINGS

Reference to the detailed description, combined with the following figures, will make the disclosure more fully understood, wherein:

FIG. 1 shows a view of the layout of a first RF-MEMS capacitive switch implementation according to an implementation of the disclosure;

FIG. 2 shows another view of the layout of a RF-MEMS capacitive switch according to an implementation of the disclosure;

FIG. 3 shows a close-up view of various components of the RF-MEMS capacitive switch of FIGS. 1 and 2;

FIG. 4 shows a view of the layout of a second RF-MEMS capacitive switch according to some implementations of the disclosure;

FIG. 5 shows a close-up view of various components of the RF-MEMS capacitive switch of FIG. 4;

FIG. 6 shows a view of the layout of a third RF-MEMS capacitive switch according to an implementation of the disclosure;

FIGS. 7A and 7B are close-up views of various components of the RF-MEMS capacitive switch of FIG. 6;

FIG. 8 shows a view of the layout of a fourth RF-MEMS capacitive switch according to an implementation of the disclosure;

FIG. 9 shows another view of the layout of the fourth RF-MEMS capacitive switch including the RF stator interconnect electrodes and the DC stator interconnect electrodes.

FIG. 10 is a close-up view of various components of the fourth RF-MEMS capacitive switch;

FIG. 11 shows a view of the layout of a fifth RF-MEMS capacitive switch according to an implementation of the disclosure;

FIGS. 12A and 12B are close-up views of various components of the RF-MEMS capacitive switch of FIG. 11;

FIG. 13 shows a view of the layout of a sixth RF-MEMS capacitive switch according to an implementation of the disclosure;

FIG. 14 is a close-up view of various components of the sixth RF-MEMS capacitive switch;

FIG. 15 is a schematic diagram of a 4 Bit DTC product demonstrator composed of eight capacitive switches interconnected to conform each of the four bits according to an implementation of the disclosure;

FIG. 16 is a flow diagram of a process for manufacturing a RF-MEMS capacitive switch according to an implementation of the disclosure; and

FIGS. 17A-17E include three-dimensional views of the RF-MEMS capacitive switch of FIG. 1.

### DETAILED DESCRIPTION

In the following description, like components have the same reference numerals, regardless of different illustrated implementations. To illustrate implementations clearly and concisely, the drawings may not necessarily reflect appropriate scale and may have certain structures shown in somewhat schematic form. The disclosure may describe and/or illustrate structures in one implementation, and in the same way or in a similar way in one or more other implementations, and/or combined with or instead of the structures of the other implementations.

In the specification and claims, for the purposes of describing and defining the invention, the terms “about” and “substantially” represent the inherent degree of uncertainty attributed to any quantitative comparison, value, measurement, or other representation. The terms “about” and “substantially” moreover represent the degree by which a quantitative representation may vary from a stated reference without resulting in a change in the basic function of the subject matter at issue. Open-ended terms, such as “comprise,” “include,” and/or plural forms of each, include the listed parts and can include additional parts not listed, while terms such as “and/or” include one or more of the listed parts and combinations of the listed parts. Use of the terms “top,” “bottom,” “above,” “below” and the like helps only in the clear description of the disclosure and does not limit the structure, positioning and/or operation of the disclosure in any manner.

Certain aspects of the present disclosure describe illustrative devices and fabrication techniques that enable more robust, responsive, and reliable RF-MEMS-based capacitive switching.

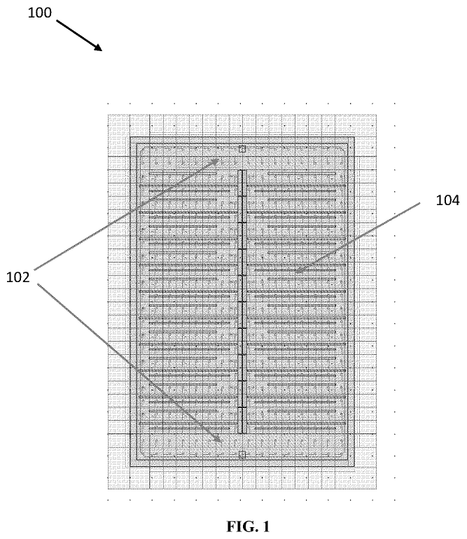

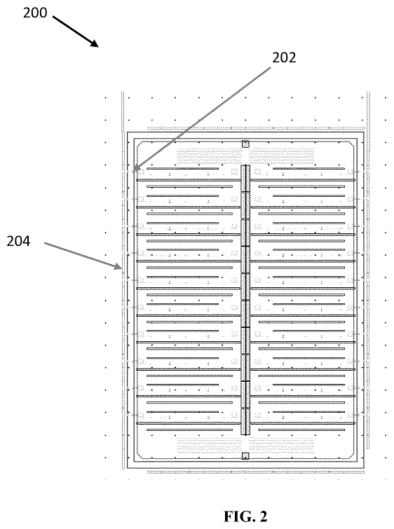

FIG. 1 shows a view of a layout of a first RF-MEMS capacitive switch 100 including meander springs 102, while FIG. 2 shows another view 200 of the layout of the RF-MEMS capacitive switch 100 including stator feedthrough 202 and stators' interconnect 204.

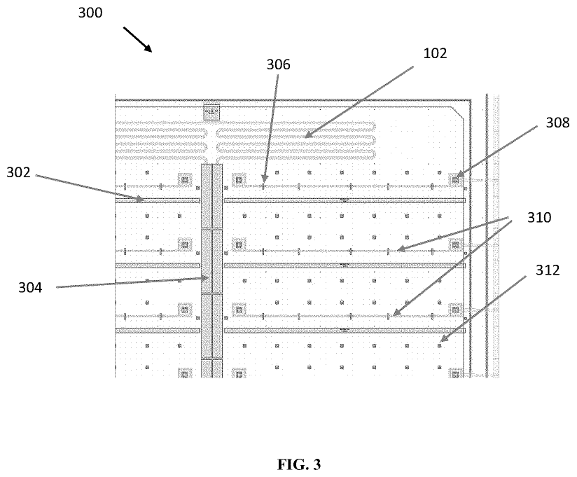

FIG. 3 shows a close-up view 300 of the upper right area of RF-MEMS capacitive switch 100. View 300 shows various components including rotor finger 302, central apex 304, stators 310, column 312, stopper 306, and capacitive anchor 308.

In some implementations, capacitive switch 100 includes 20-unit cells 104 of one stator and one rotor with out of plane or in plane actuation. In one implementation, capacitive switch 100 is actuated by application of an electrostatic force between stator 310 and rotor 302 when a voltage difference is applied between them. Multiple, e.g., five, stoppers 306 may be attached to a bottom layer (i.e., M1 layer) and a top layer (i.e., M6 layer) and may be positioned strategically to prevent contact between them. Stator 310 may be anchored to the bottom layer via two capacitive anchors 308 while the rotor's finger 302 may be attached to central apex 304. In various implementations, central apex 304 is suspended via at least one or two meander springs 102, where each one is positioned on one of the opposing ends of central apex 304. Central apex 304 may be electrically anchored to the bottom layer. The bottom layer (M1 layer) may be connected to one or more cavity sidewalls. The top layer (M6 layer) may include capping and/or a cover and form one of the electrodes of the capacitive switch 100, i.e., associated with rotor 302.

All the stators 310 of each side of central apex 304 may be interconnected via an external line at an intermediate layer between layers M1 and M6 (e.g., M2 layer) along the length of an air cavity housing and/or box 1752. For each stator 310, a two walls feedthrough 202 (extending through the wall of housing 1752) connects them to the external M2 line 204 to form the other capacitive switch 100 electrode, i.e., associated with stators 310. Square columns 312 between the top and bottom layers are distributed all along the air cavity of housing 1752 to prevent the top layer (M6 layer) from bending after release. The top layer (M6 layer) capping and/or cover over the cavity of the capacitive switch 100 may include holes to ensure that the release process of the air cavity can be done properly. In some implementations, a maximum capacitance ratio Cr=1.2 (20%) and a quality factor Q=5. In one implementation, rotor finger length may be about 45 um, rotor finger height may be about 4-9 um, the air gap between a rotor and stator may be about 2 um, and stopper diameter may be less than or equal to about 500 nm.

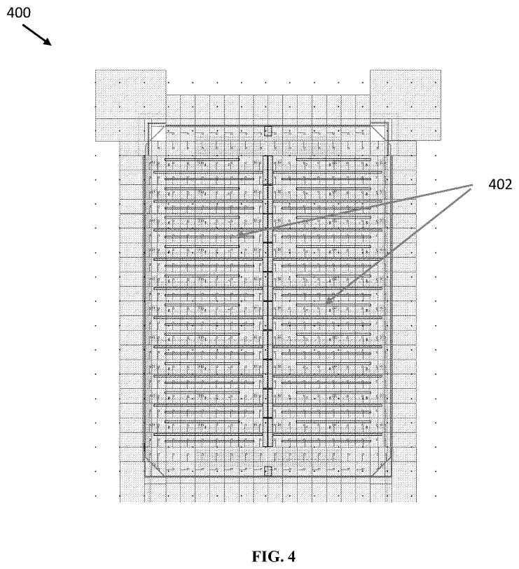

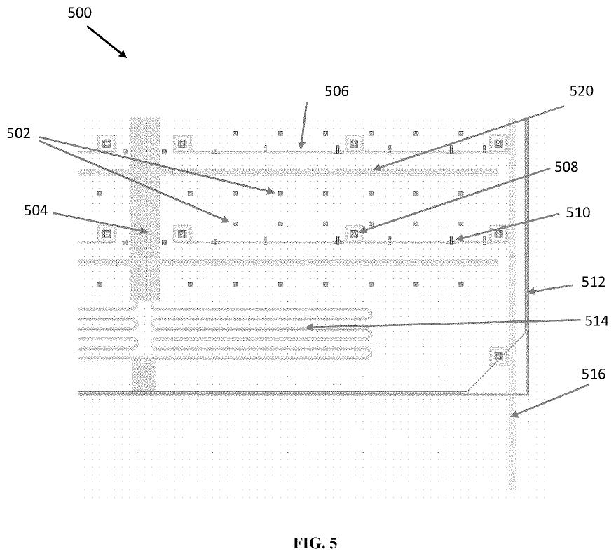

FIG. 4 shows a view of the layout of a second RF-MEMS capacitive switch 400 according to some implementations of the disclosure. FIG. 5 shows a close-up view 500 of the lower right quadrant of capacitive switch 400 including various components of the RF-MEMS capacitive switch 400 such as columns 502, central apex 504, stator 506, capacitive anchor 508, stopper 510, air cavity wall 512, external interconnect 516, and meander spring 514.

Capacitive switch 400 may also be referred as G2v1 (generation 2 version1, or Version v1a). In some implementations, a main difference with capacitive switch 100 (i.e., Version v1) is that the line interconnecting stators 516 is routed inside the air cavity housing instead of outside the air cavity housing. In this way, EM field interactions with the IMD are reduced and the Q is improved from 4 to about 20.

Capacitive switch 400 may be composed of multiple rotor-stator cell 402 such as 18-unit cells of one stator and one rotor for DC actuation and two (2) unit cells of one stator and one rotor for RF variable capacitance, both parts with out of plane or in plane actuation. Capacitive switch 400 may be actuated by application of an electrostatic force between a DC stator and rotor when a voltage difference is applied between them. Multiple stoppers 510, e.g., five stoppers, may be attached to bottom layer M1 and top layer M6 and may be placed strategically to prevent contact between the stators and rotor and/or the M1 and M6 layers. A stator, such as stator 506, may be anchored to the bottom M1 layer using one or more capacitive anchors 508, e.g., three capacitive anchors, while a rotor's finger, e.g., rotor finger 518, may be attached to central apex 504.

In some implementations, central apex 504 is suspended using one or more, e.g., two meander springs 514, where the one or more meander springs 514 are connected to at least one end of central apex 504. The central apex 504 may be connected to the bottom layer M1. The bottom layer (e.g., M1 layer) may be connected to cavity sidewalls while the top layer (e.g., M6 layer) may include capping and/or a cover conforming one of the electrodes of capacitive switch 400, e.g., associated with the rotor connected to DC and RF grounds. Each stator of each side, e.g., stator 510, may be interconnected using, for example, an internal line at an intermediate layer between the M1 and M6 layers (e.g., the M3 layer) along the length of the air cavity housing and/or box conforming the other DC+RF electrode for electrostatic actuation and RF variable capacitance, e.g., associated with the stator of capacitive switch 400.

Square columns 502 between bottom and top layers (M1 and M6 layers) are distributed all along the air cavity to prevent the top layer (M6 layer) from bending after release. The top layer (M6 layer) capping over the cavity may include holes to ensure that the release process of the air cavity can be done properly. In some implementations, capacitive switch 400 has a maximum capacitance ratio Cr=1.2 (20%) and quality factor Q=20. In one implementation, rotor finger length may be about 45 um, rotor finger height may be about 4-9 um, the air gap between a rotor and stator may be about 2 um, and stopper diameter may be less than or equal to about 500 nm.

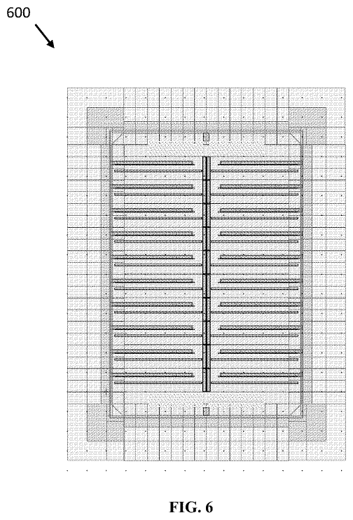

FIG. 6 shows a view of the layout of a third RF-MEMS capacitive switch 600 according to an implementation of the disclosure. In certain implementations of capacitive switch 600, the bottom layer (M1 layer) is not electrically connected to cavity sidewalls and the top layer and/or metal. Capacitive switch 400 may not have a top layer (M6 layer) and/or metal capping (i.e., capacitive switch 400 has an open structure intended for, for example, wafer capping packaging). Rotor fingers, e.g., fingers 708, may be attached to central apex 706 and central apex 706 attached to the bottom layer (M1 layer). Stator fingers, including finger 708, may be attached to cavity sidewalls. In some implementations, there is no decoupling between RF and DC.

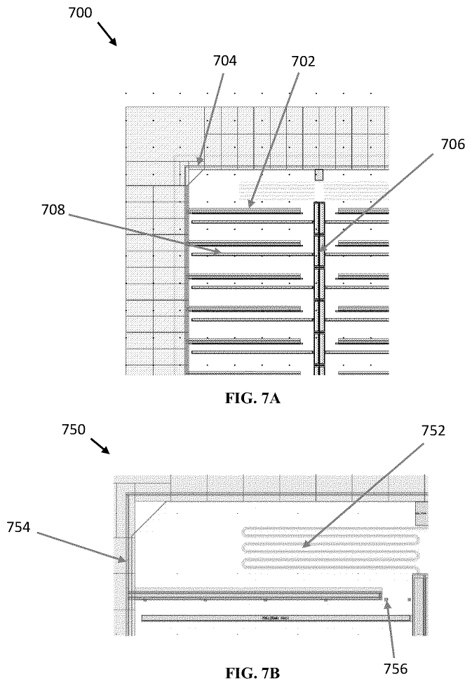

FIGS. 7A and 7B are close-up views 700 and 750 respectively of various components of the RF-MEMS capacitive switch 600 including stators' interconnect 704, stator 702, central apex 706, rotor finger 708, meander spring 752, air cavity wall 754, and stopper 756. Capacitive switch 600 may include multiple unit cells, e.g., 20-unit cells, with each having one stator and one rotor with out of plane or in plane actuation. Capacitive switch 600 may be actuated by application of an electrostatic force between its stator and rotor when a voltage difference is applied between them. The stator, including stator 702, may be attached to internal cavity sidewalls while the the rotor's fingers, e.g., rotor finger 708, may be attached to central apex 706.

The central apex 706 may be suspended using at least one meander spring 752, e.g., using two meander springs, where the at least one meander spring is connected to one of end of central apex 706. The central apex 706 may be connected to the bottom layer (M1 layer), conforming the rotor electrode. The bottom layer (M1 layer) may be unconnected to the air cavity sidewalls. All the stators, such as stator 702, of each side of central apex 706 may be interconnected using the internal side walls of the air cavity housing and/or box, to form a stator electrode of the capacitive switch 600. Five stoppers, including stopper 756, may be connected to the bottom layer (M1 layer) and an overlapping stator and may be distributed along the stator to prevent contact between rotor and stator when actuated. A stator, e.g., stator 702, may be implemented using a M2 layer to M6 layer stack to, thereby, increase a variable capacitance area. In some implementations, there is no M6 layer capping and, therefore, no columns are required, but wafer capping may be required for packaging. A stator, e.g., stator 702, may be biased by the M6 layer while a rotor, e.g., rotor 708, may be biased by the M1 layer. In some implementations, capacitive switch 600 realizes an improved Capacitance ratio Cr=2 (100%) and Q=20. In one implementation, rotor finger length may be about 45 um, rotor finger height may be about 7 um, the air gap between a rotor and stator may be about 2-5 um, and stopper diameter may be about 200 nm.

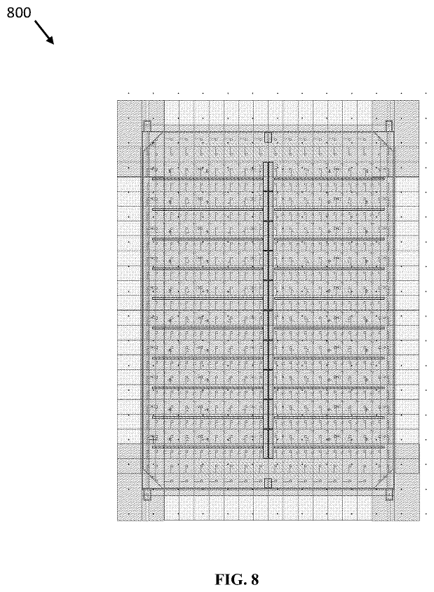

FIG. 8 shows a view of the layout of a fourth RF-MEMS capacitive switch 800 according to an implementation of the disclosure. In some implementations, capacitive switch 800 is based on the design of capacitive switch 400 (e.g. Version v1a) but with DC to RF isolation. In this implementation, the stators' interconnecting line is divided into two parts so that the DC and RF stator's electrodes can be accessed independently, while the rotor is connected to a ground air cavity housing.

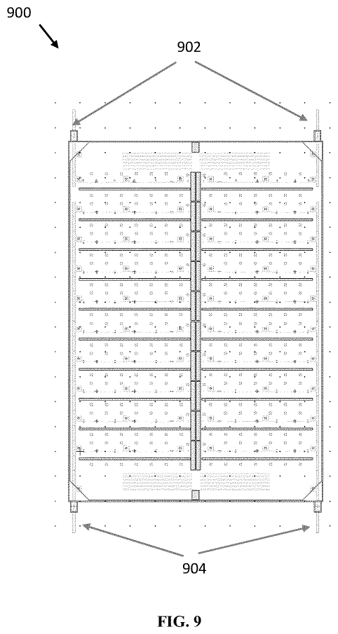

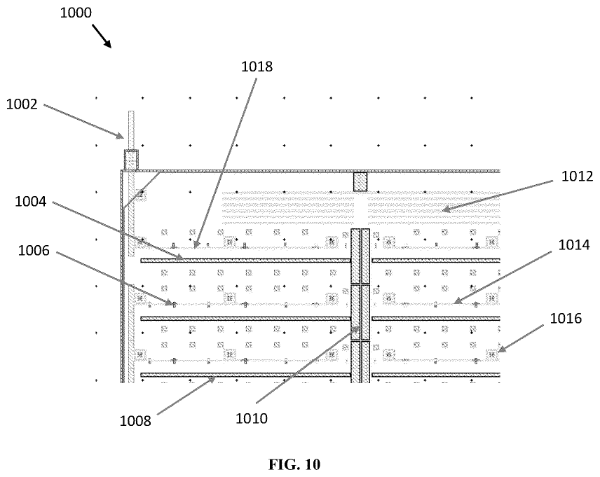

FIG. 9 shows another view 900 of the layout of the fourth RF-MEMS capacitive switch 800 including the RF stator interconnect electrodes 902 and the DC stator interconnect electrodes 904. FIG. 10 is a close-up view 1000 of various components of the fourth RF-MEMS capacitive switch including RF access and/or input 1002, RF rotor finger 1004, DC rotor finger 1006, stopper 1008, central apex 1010, meander spring 1012, DC stator 1014, capacitive anchor 1016, and RF stator 1018.

Capacitive switch 800 may include multiple unit cells, e.g., 18-unit cells, of one stator and one rotor for DC actuation and two unit cells of one stator and one rotor for RF variable capacitance, both parts with out of plane or in plane actuation. The capacitive switch 800 may be actuated by using an electrostatic force between a DC stator and rotor when a voltage difference is applied between them. Multiple stoppers, e.g., five stoppers including stopper 1006, may be attached to M1 layers and M6 layer and placed strategically to prevent contact between them.

The stator may be anchored to the M1 layer via multiple, e.g., three, capacitive anchors, such as anchor 106, while the rotor's fingers, such as rotor finger 1004, may be attached to central apex 1010. The central apex 1010 may be suspended by at least one meander spring 1012, including by two meander springs where each one is coupled to opposing ends of central apex 1010. The central apex 1010 may be connected to the M1 layer. The M1 layer may be connected to cavity sidewalls. The M6 layer may include capping conforming one of the electrodes of capacitive switch 800, associated with the rotor connected to DC and RF ground. In one implementation, nine stators on each side of central apex 1010 are interconnected using an internal line, at an intermediate layer such as the M3 layer, along the length of the air cavity housing and/or box conforming the other DC electrode for electrostatic actuation, associated with the DC stator.

The RF stators including RF stator 1018 may be connected to the M1 layer using multiple, e.g., three, capacitive anchors including capacitive anchor 1016. In one implementation, two RF stators are connected to an internal M3 layer line that extends out of the air cavity via a two wall feedtrough to form an RF input connection 1002. Two RF rotor fingers including rotor finger 1004 may be attached to central apex 1010 that is connected to ground forming a second RF electrode of the RF variable capacitance. Square columns between the M1 layer and M6 layer may be distributed all along the air cavity to prevent the M6 layer from bending after release. The M6 layer may include capping over the cavity that has holes to ensure that the release process of the air cavity can be done properly. In one implementation, rotor finger length may be about 45 um, rotor finger height may be about 7 um, the air gap between a rotor and stator may be about 2-5 um, and stopper diameter may be about 200 nm.

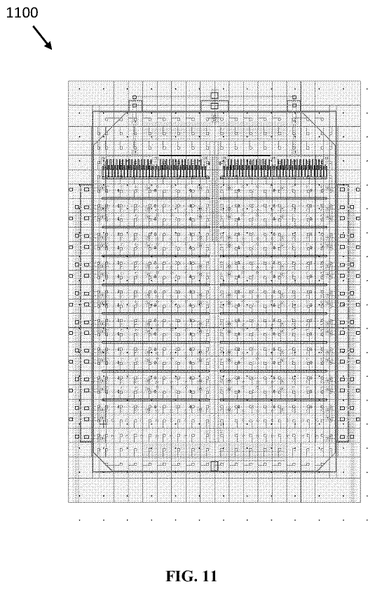

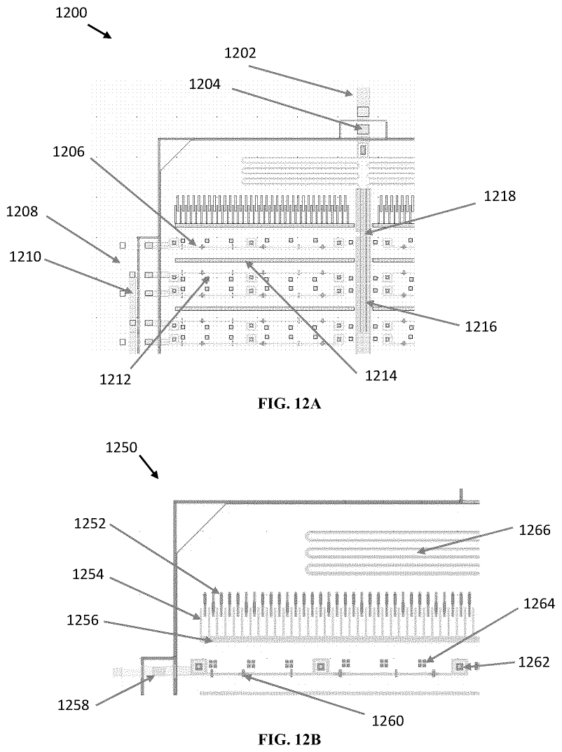

FIG. 11 shows a view of the layout of a fifth RF-MEMS capacitive switch 1100 (referred to as Version G6v6) according to an implementation of the disclosure. In one implementation, capacitive switch 1100 provides isolation between RF and DC signals. Central apex 1216 has a capacitive anchorage including capacitive anchor 1262 that provides electrical isolation between RF and DC parts of capacitive switch 1100. In one implementation, capacitive switch 1100 includes pull-on/pull-off DC electrodes that increase the rotor's displacement and ensure there is no self actuation. To increase Cr, teeth may be added to the RF rotor fingers. FIGS. 12A and 12B are close-up views 1200 and 1250 respectively of various components of the RF-MEMS capacitive switch 1100 including: RF input 1202, RF input feedthrough 1204, DC pull-on stators 1206 and 1212, DC pull-on stator electrodes interconnect 1208, DC pull-off stator electrodes interconnect 1210, DC rotor finger 1214, central apex 1216, apex capacitive anchor 1218, RF stator 1252, RF rotor finger 1256, RF rotor teeth 1254, DC stator feedthrough 1258, capacitive anchor 1262, stoppers 1260, and columns 1264.

In some implementations, capacitive switch 1100 includes multiple unit cells, e.g., 18-unit cells, of two stator (one for pull on and the other for pull-off) and one rotor for DC actuation and two unit cells of one stator and one rotor for RF variable capacitance, both parts having out of plane or in plane actuation. Capacitive switch 1100 ma be actuated using an electrostatic force between any of the two DC stator (pull-on or pull-off) and rotor when a voltage difference is applied between them. Rotor DC fingers such as finger 1214 may be attached to central apex 1216 as well as RF rotor finger 1256. But, both parts of central apex 1216 are isolated using a capacitive anchorage such as via anchor 1218 that provides isolation between RF and DC signals.

In some implementations, RF rotor's finger 1256 has several teeth 1254 attached to it orthogonal to its length. The central apex 1216 may be suspended by at least one meander spring 1266 or two meander springs where each one is coupled to opposing ends of central apex 1216.

In one implementation, on the DC part of apex 1216, meander spring 1266 is connected to the M1 layer, while on the RF part of apex 1216, the meander spring is attached to the M1 layer using a capacitive anchor which is connected to RF input line 1202 via a double wall vertical feedthrough 1204 to get out of the air cavity, and forming the RF input electrode. Multiple stoppers, e.g., six, may be attached to the M1 layer and M6 layer, and positioned strategically in a spaced manner along the DC pull-on/pull-off stator length while overlapping it to prevent contact between DC rotor and stator when a pull-in voltage is applied between DC pull-off or pull-on electrode and the DC rotor.

Both DC stators 1206 and 1212 may be anchored to the M1 layer using multiple, e.g., three, capacitive anchors and then connected to the proper DC pull-on or DC pull-off line via a double wall vertical feedthrough to get out of the air cavity. The RF stator may be implemented using vertical walls (from M2 layer to M5 layer) attached to the M1 layer and M6 layer, while orthogonal to the rotor displacement, allowing RF teeth 1254 attached to the rotor's RF finger 1256 to overlap RF stator walls when a pull-in voltage is applied to the DC pull-on electrodes. The RF stator may be connected to the M1 layer as well as the DC rotor, to form the grounded RF electrode and DC electrodes.

In one implementation, two external lines to the air cavity along the air cavity are interconnect all the DC pull-on electrodes, forming the DC pull-on electrode, and the other interconnect for all the DC pull-off electrodes, forming the DC pull-off electrodes. Square columns such as column 1264 between the M1 and M6 layers may be distributed all along the air cavity to prevent the M6 layer from bending after release. M6 layer capping over the cavity may include holes to ensure that the release process of the air cavity can be done properly.

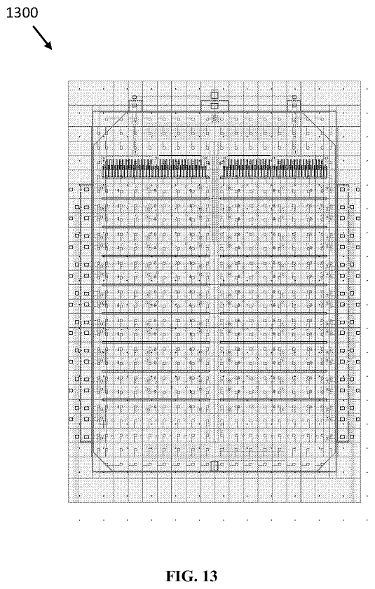

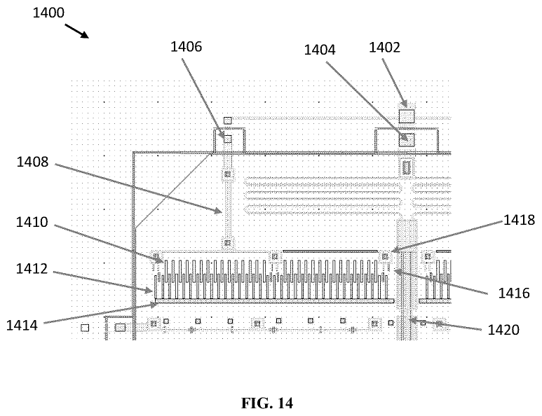

FIG. 13 shows a view of the layout of a sixth RF-MEMS capacitive switch 1300 (referred to as Version G7v6c) according to an implementation of the disclosure. FIG. 14 is a close-up view 1400 of various components of the sixth RF-MEMS capacitive switch 1300 including: RF input 1402, RF input feedthrough 1404, RF stopper feedthrough 1406, RF stoppers interconnect line 1408, RF stator 1410, RF rotor finger 1414, RF rotor teeth 1412, RF stoppers 1416, and RF stopper capacitive anchor 1418. The configuration of capacitive switch 1300 is similar to the configuration of capacitive switch 1100, but with three additional capacitive anchors attached to the M1 layer on the RF unit cell to act as stoppers for the RF rotor. In one implementation, these stoppers are interconnected by a M3 layer line that is suspended inside the air cavity using two capacitive anchors and such that the line extends out of the air cavity via a double wall feedthrough and is then connected to RF input line 1402. The implementation of capacitive switch 1300 has a capacitance ratio Cr=2,4 (100%)/Q=100.

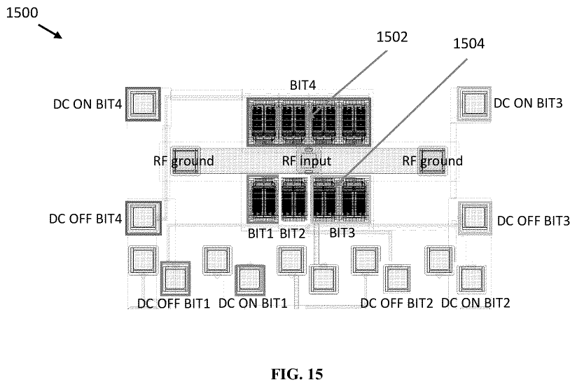

FIG. 15 is a schematic diagram of a 4 Bit DTC product demonstrator 1500 including eight capacitive switches in two groups 1502 and 1504 interconnected to form each of the four bits according to an implementation of the disclosure. In one implementation, the demonstrator 1500 includes two arrays 1502 and 1504 of four capacitive switches each. The array 1504 implements bit1 to bot 3 and array 1502 implements bit4. Bit 1 is implemented with a capacitive switch 1300 (i.e., G7v6c) with one RF unit cells. Bit 2 is implemented with a capacitive switch 1300 (G7v6c) with two RF unit cells. Bit 3 is implemented with two capacitive switches 1300 (G7v6c) with two RF unit cells. Bit4 is implemented with four capacitive switches 1300 (G7v6c) with two RF unit cells. Each capacitive switch has its RF input connected to the central PADS of the GSG PADS using a Metal top line. Each bit has one DC connection to its DC pull-on stators and other one to its DC pull-off stators.

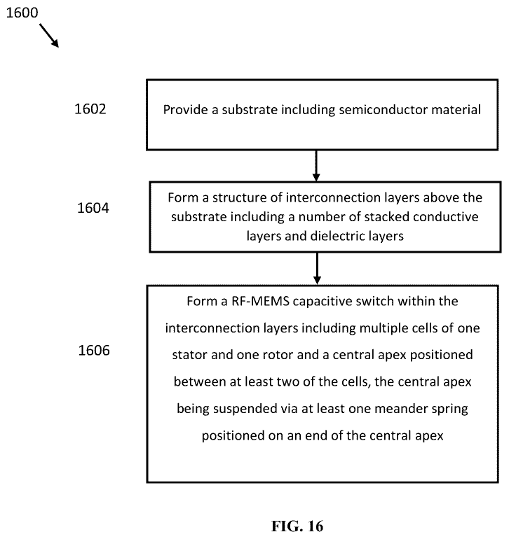

FIG. 16 is a flow diagram of a process 1600 for manufacturing a RF-MEMS capacitive switch according to an implementation of the disclosure. Process 1600 includes: providing a substrate including semiconductor material (Step 1602); forming a structure of interconnection layers above the substrate including a number of stacked conductive layers and dielectric layers (Step 1604); forming a plurality of cells within the interconnect layers, each cell having one stator and one rotor and forming a central apex positioned between at least two of the cells, the central apex being suspended via at least one meander spring positioned on an end of the central apex (Step 1606). Process 1600 may also include forming two meander springs, where each meander spring is coupled to an opposing end of the central apex. A CMOS chip typically includes an inter dielectric layer (ILD) between the silicon substrate and the interconnect layers. In various implementations, formation of various components of the MEMS elements of a capacitive switch includes formation and/or etching of the elements within the interconnect layers of a chip using highly reactive etchant gases such as vapor hydrogen fluoride (vHF). To prevent excessive etching of the ILD or silicon substrate, a conductor layer (or conductive metal layer), which is resistant to vHF, can be positioned between the ILD and interconnect layers to prevent excessive etching by the vHF of the ILD and/or substrate. A conductor and/or layer may be positioned above the MEMS capacitive switch and include one or more holes (e.g., the M6 layer or another layer), aligned above various MEMS components of a capacitive switch, that allow for the passage of vapor HF (vHF) into one or more interconnect layers to effect the release of the MEMS components of a capacitive switch such as the switches described herein.

In various implementations, vHF (i.e., Hydrofluhidric Acid in a vapour stage) is applied to a finished CMOS wafer to etch away silicon oxide at the back-end of the CMOS process, i.e., it etches away the SiO2 that lies in between the metal layers of the CMOS wafer to free up the metals, which are used to implement the MEMS capacitive switch. This process may only be implemented in some areas of the wafer and the chips, which are delimited by the same design. Metal layers may be used to block the vHF outside the MEMS cavity. In various implementations, the limitation of the vHF actuation and/or etching is set by the metal design and/or the passivation opening. That is the design in the layer corresponding to the passivation opening.

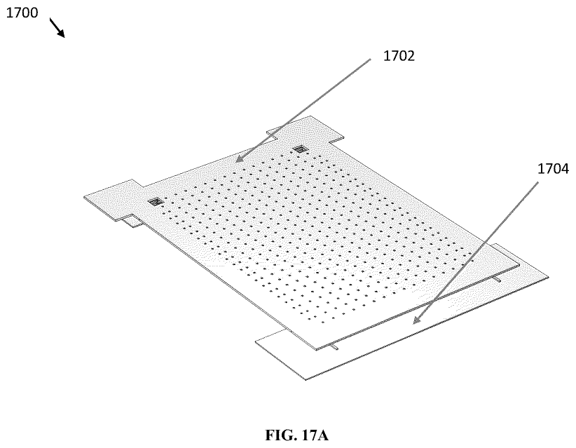

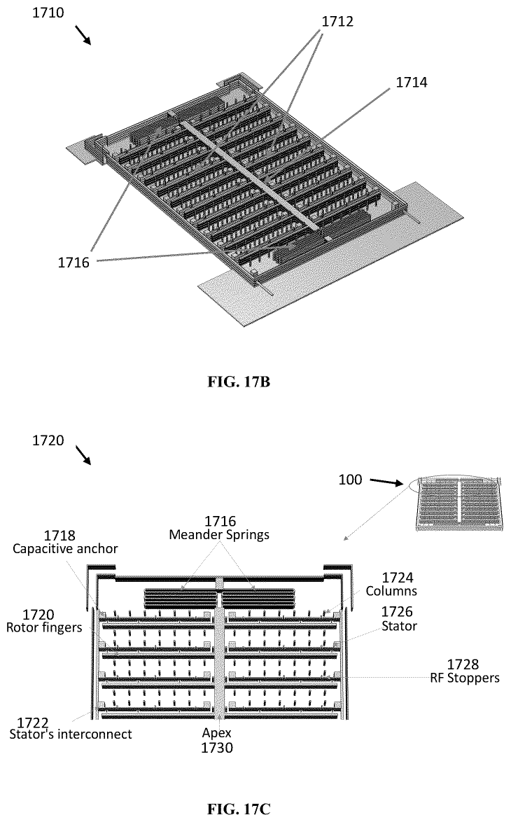

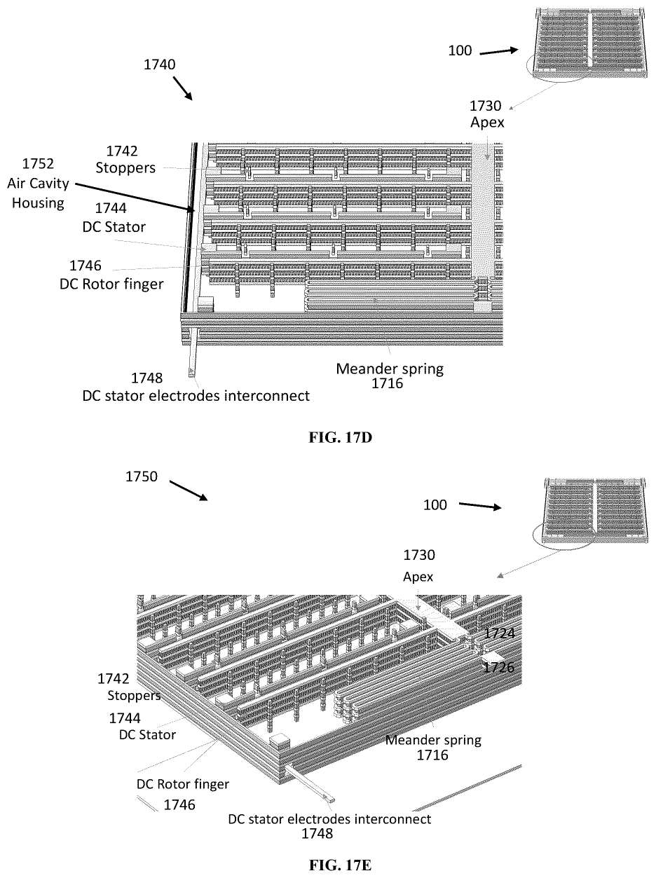

FIGS. 17A-17E include three-dimensional views of the RF-MEMS capacitive switch of FIG. 1. FIG. 17A shows a perspective view of capacitive switch 100 with top layer (M6 layer) 1702 and bottom layer (M1 layer) 1704. FIG. 17B includes view 1710 of capacitive switch 100 showing meander springs 1716, unit cells 1712, and central apex 1714. FIG. 17C shows view 1720 including a close-up view of the top portion of capacitive switch 100 including meander spring 1716, capacitive anchor 1718, rotor fingers 1720, stator interconnect 1722, columns 1724, stator 1726, RF stopper 1728, and central apex 1730. FIG. 17D shows view 1740 including stoppers 1742, air cavity housing 1752, DC stator 1744, DC rotor finger 1746, DC stator's electrode interconnect 1748. FIG. 17E shows another view 1750 of the component shown in view 1740.

Elements of different implementations described may be combined to form other implementations not specifically set forth previously. Elements may be left out of the systems described previously without adversely affecting their operation or the operation of the system in general. Furthermore, various separate elements may be combined into one or more individual elements to perform the functions described in this specification.

1. A RF-MEMS capacitive switch comprising:
a central apex;
a plurality of cells, at least two of the plurality of cells being coupled to opposing sides of the central apex, each of plurality of cells including a rotor and a stator;
at least one meander spring coupled to an end of the central apex;
a top layer; and
a bottom layer.

2. The capacitive switch of claim 1 further comprising two meander springs, each meander spring being coupled to an opposing end of the central apex.

3. The capacitive switch of claim 1, wherein the capacitive switch is actuated in response to an electrostatic force being applied between the stator and the rotor when a voltage difference is applied between them.

4. The capacitive switch of claim 3, wherein the rotor and stator are actuated via one of an out of plane actuation and an in plane actuation.

5. The capacitive switch of claim 1 comprising a plurality of stoppers extending between the top and bottom layers of the capacitive switch to maintain separation between the rotor and stator of each of the plurality of cells.

6. The capacitive switch of claim 1 comprising a plurality of capacitive anchors configured to anchor the stator to the bottom layer.

7. The capacitive switch of claim 1, wherein the bottom layer includes an M1 layer and the top layer includes an M6 layer.

8. The capacitive switch of claim 1, wherein the rotor includes a rotor finger that is coupled to the central apex.

9. The capacitive switch of claim 1, wherein the central apex is electrically coupled to the bottom layer.

10. The capacitive switch of claim 1 comprising at least one cavity wall extending at least partially between the bottom and top layers, the at least one cavity wall being coupled to the bottom layer.

11. The capacitive switch of claim 10 comprising an air cavity housing arranged adjacent to a portion of the at least one cavity wall.

12. The capacitive switch of claim 11 comprising a plurality of cells on each side of the central apex, wherein each of the stators of the cells on a side of the central apex are interconnected via an external line at a layer between the bottom and top layers and along the length of the air cavity housing.

13. The capacitive switch of claim 12, wherein the air cavity housing is defined by an inner wall and an outer wall, and wherein each of the stators are connected to the external line via a feedthrough in the inner and outer walls, to form a first capacitive switch electrode.

14. The capacitive switch of claim 13, wherein the top layer includes a second electrode of the capacitive switch.

15. The capacitive switch of claim 1, further comprising a plurality of columns between the top layer and bottom layer, the plurality of columns being distributed along the air cavity housing to prevent the top layer from bending after release.

16. The capacitive switch of claim 1, wherein the top layer includes capping over at least one cavity formed by the capacitive switch, the capping including a plurality of holes to facilitate a release process of the at least one air cavity.

17. A RF-MEMS capacitive switch comprising:
a central apex;
a plurality of cells, at least two of the plurality of cells being coupled to opposing sides of the central apex, each of plurality of cells including at least one rotor and at least one DC pull on stator;
at least one meander spring coupled to an end of the central apex;
a top layer; and
a bottom layer.

18. The capacitive switch of claim 17, when the at least one rotor includes an RF rotor finger and RF rotor teeth.

19. A method for manufacturing a RF-MEMS capacitive switch comprising:
providing a substrate including semiconductor material;
forming a structure of interconnection layers above the substrate including a number of stacked conductive layers and dielectric layers; and
forming a plurality of cells within the interconnect layers, each cell having one stator and one rotor; and
forming a central apex positioned between at least two of the cells, the central apex being suspended via at least one meander spring positioned on an end of the central apex;
wherein forming the plurality of cells and the central apex includes releasing one or more of the plurality of cells and central apex using vHF etching.

20. The method of claim 19 comprising forming two meander springs, each meander spring being coupled to an opposing end of the central apex.
